(19) United States
(12) Patent Application Publication
(10) Pub. No.: US 2012/0135596 A1
(43) Pub. Date: May 31, 2012

(54) METHOD OF REMOVING NANOCRYSTALS

(76) Inventors: Sung-Taeg Kang, Austin, TX (US); Jinmiao J. Shen, Austin, TX (US)

(21) Appl. No.: 12/022,800

(22) Filed: Jan. 30, 2008

(51) Int. Cl. H01L 21/28; H01L 21/31

(52) U.S. Cl. 438/594; 438/778; 257/E21.209; 257/E21.24

(57) ABSTRACT

A method for forming a semiconductor structure includes providing a semiconductor layer, forming nanocrystals over the semiconductor layer, and using a solution comprising pure water, hydrogen peroxide, and ammonium hydroxide to remove at least a portion of the nanocrystals. A ratio by volume of pure water to ammonium hydroxide of the solution may be equivalent to or less than a ratio by volume of 10:1 of pure water to ammonium hydroxide when ammonium hydroxide has a concentration of 29% ammonia by weight. The step of using the solution to remove the at least a portion of the nanocrystals may be performed at a temperature of 50 degrees Celsius or more.

### BACKGROUND

1. Field

This disclosure relates generally to non-volatile memories, and more specifically, to removing nanocrystals useful in non-volatile memories.

2. Related Art

Nanocrystals are recognized as having benefits over using a floating gate in a non-volatile memory (NVM). There are difficulties, however, that make manufacturing NVMs with nanocrystals problematic. One such difficulty is removing nanocrystals from areas where they are not desired such as over source/drain regions. Removing a floating gate over an oxide layer that protects a source/drain can be achieved without penetrating through the protective oxide. This is more difficult with nanocrystals because the portions of the protective oxide that are not covered with nanocrystals are exposed to the etchant for the entire duration of the etch of the nanocrystals. Thus the exposed portions of the protective oxide can be etched all the way through to the underlying silicon substrate before the nanocrystals are completely removed. If the protective oxide is etched through, then the substrate is exposed to the etchant that etches silicon until the nanocrystal etch is complete. In such case, there would likely be catastrophic damage to the substrate. This potential for this problem has gotten significantly worse as the desirable diameter has been increasing. In the past, 50 Angstroms was considered a typical diameter. Now it has been found desirable that the diameter exceed 100 Angstroms. Another technique that has been used is simply to remove the underlying oxide layer to remove the nanocrystals. This type of removal is sometimes called a wash away method. This too has been found to be difficult to achieve reliably with the increase in size of nanocrystals. The increased nanocrystal size makes it difficult to sufficiently undercut the nanocrystals to reliably remove all of them.

Accordingly, there is a need for a method for removing nanocrystals that effectively improves upon the issues raised above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a cross section of a semiconductor device at a stage in processing according to an embodiment;

FIG. 2 is a cross section of the semiconductor device of FIG. 1 at a subsequent stage in processing;

FIG. 3 is a cross section of the semiconductor device of FIG. 2 at a subsequent stage in processing;

FIG. 4 is a cross section of the semiconductor device of FIG. 3 at a subsequent stage in processing;

FIG. 5 is a cross section of the semiconductor device of FIG. 4 at a subsequent stage in processing; and

FIG. 6 is a cross section of the semiconductor device of FIG. 5 at a subsequent stage in processing;

### DETAILED DESCRIPTION

In one aspect, nanocrystals are deposited over a protective layer that is over a semiconductor substrate. The nanocrystals are removed using an etchant that includes water, ammonium hydroxide, and hydrogen peroxide. The etchant is effective in removing even nanocrystals of greater than 100 Angstroms without penetrating through the underlying protective layer even with the protective layer being oxide of less than 100 Angstroms, such as 60 Angstroms. Raising the temperature to above 50 degrees and having the ratio, by volume, of water to ammonium hydroxide (from commercially available material at 30% ammonium hydroxide) be 10 or below has been found to speed up the process while still retaining high selectivity to oxide.

A semiconductor substrate 12 described herein can be any semiconductor material or combinations of materials, such as gallium arsenide, silicon germanium, silicon-on-insulator (SOI), silicon, monocrystalline silicon, the like, and combinations of the above.

Shown in FIG. 1 is a semiconductor device 10 comprising substrate 12, a gate dielectric 14 over substrate 12, a select gate layer 16 over gate dielectric 14, an anti-reflective coating (ARC) 18 on the top of select gate layer 16, a protective layer 20 along the sidewalls of gate 16 and over substrate 12 in areas adjacent to gate 16, a plurality of nanocrystals 24 over protective layer 20, an insulating layer 28 over and around plurality of nanocrystals 24, and a control gate layer 30 over insulating layer 28. Nanocrystal 26 is a nanocrystal of plurality of nanocrystals 24 that is to be removed. The diameter of the nanocrystals is preferably about 120 Angstroms. The diameters can vary significantly from nanocrystal to nanocrystal. Protective layer 20 may be about 60 Angstroms and preferably oxide but could be another material. Oxide is beneficial because of its ability to be grown and its ability to be etched with minimal effect on the underlying substrate. Plurality of nanocrystals 24 are preferably polysilicon. ARC layer 18 is preferably nitride. Insulating layer 28 may be about 200 Angstroms in thickness and is preferably oxide but could be another material. Control gate layer 30 and select gate layer 16 are preferably polysilicon but could be another material and may be about 1000 Angstrom in thickness.

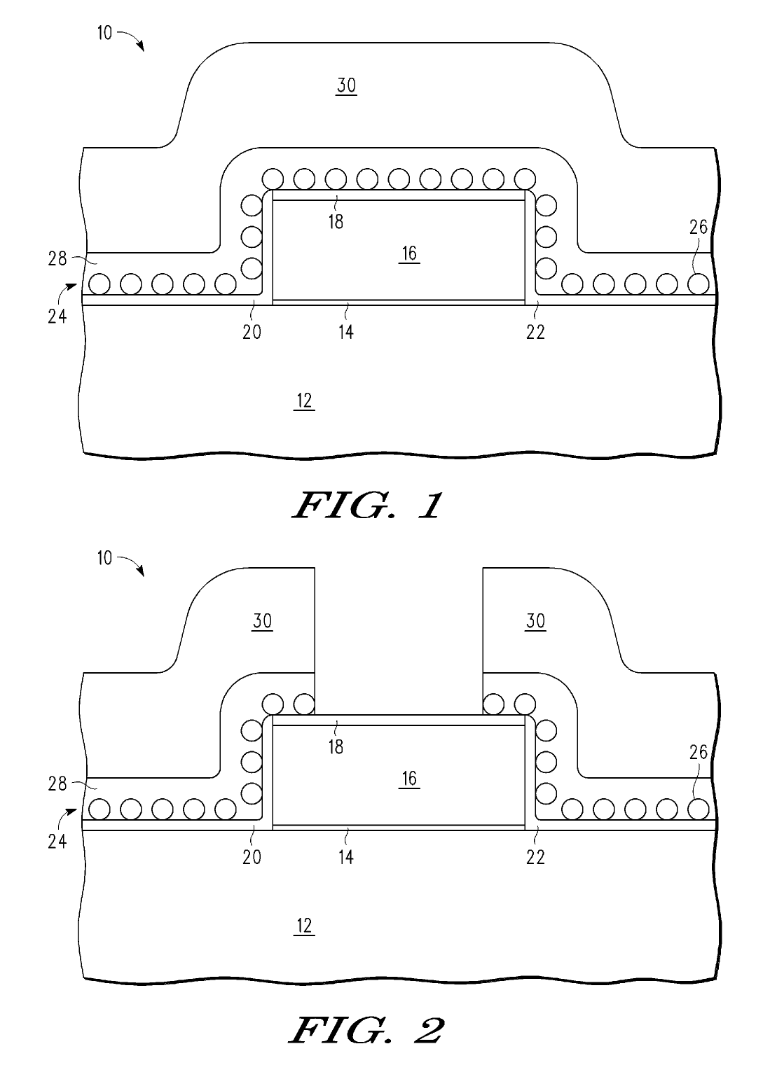

Shown in FIG. 2 is semiconductor device 10 after performing a patterned etch of control gate layer 30. This etch opens an area over select gate layer 16. This is a dry etch that stops on ARC 18. This leaves portions of control gate layer 30 over the corner areas of select gate layer 16 and over substrate 12 on the sides of select gate layer 16.

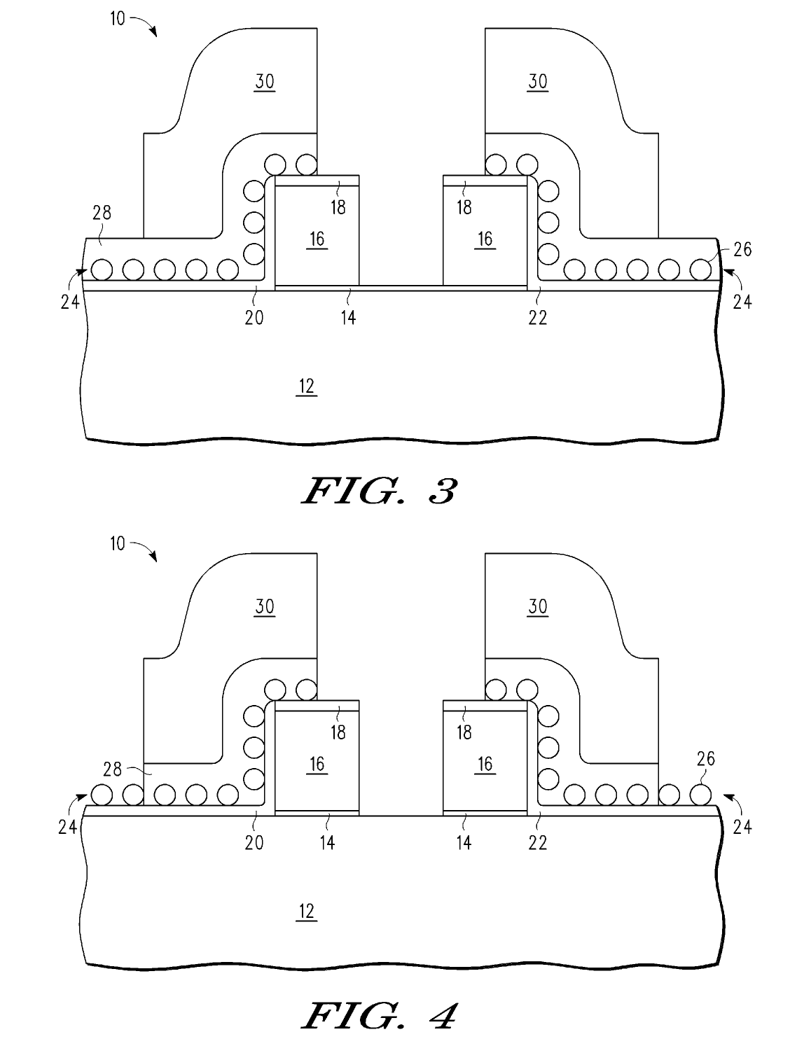

Shown in FIG. 3 is semiconductor device 10 after performing a patterned etch through ARC 18 and select gate 16 which leaves first portions of select gate layer 16 under the remaining portions of control gate layer 30 and second portions exposed outside of the remaining portions of control gate layer 30. This etch also is removes portions of control gate layer 30 to provide the final definition for the control gates to two NVM cells. Similarly, the remaining portions of select gate layer 16 provide the control gates for the two NVM cells.

Shown in FIG. 4 is semiconductor device 10 after removing the portion of insulating layer 28 not covered by the remaining portions of select gate layer 30. This exposes the nanocrystals that are to be removed. Nanocrystal 26 is exemplary of the nanocrystals that are exposed and to be removed.

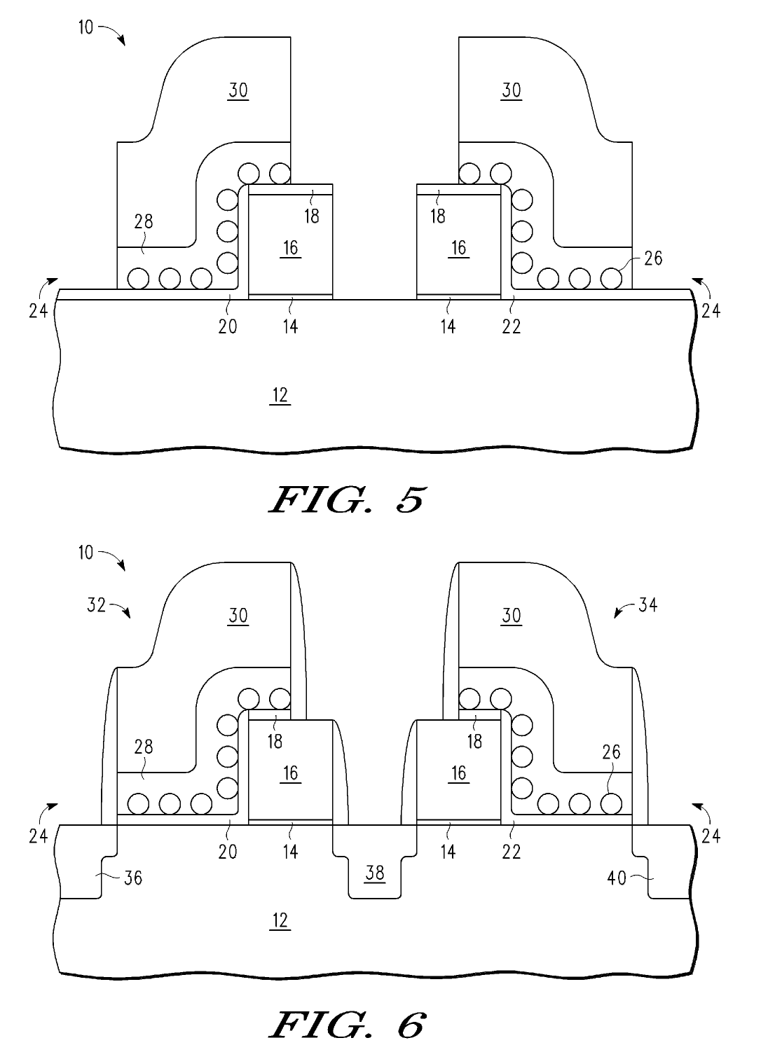

Shown in FIG. 5 is semiconductor device 10 after removing the nanocrystals of plurality of nanocrystals 24, including nanocrystal 26, that are exposed which are the ones that are not covered by the remaining portions of control gate 30. This removal is achieved in an etchant comprising ammonium hydroxide, hydrogen peroxide, and water. This is a solution that is preferably heated to a temperature above 50 degrees Celsius and has a ratio, by volume, of water to ammonium hydroxide of ten or less to one. The hydrogen peroxide may be the same content as the ammonium hydroxide although that may not be required. These three materials have been commonly combined in a ratio, by volume, of 20:1:1 (water:ammonium hydroxide:hydrogen peroxide) to form what is commonly referenced as SC1 which is used at room temperature as a clean for removing organic particles that are an unwanted residue. This ratio is for using commercially available ammonium hydroxide and hydrogen peroxide. In particular, the ammonium hydroxide is commercially available from a solution in which there is 29.4% ammonia by weight, and the hydrogen peroxide is commercially available from a solution that is 30% hydrogen peroxide by weight. It should be noted that it has not been found possible to isolate ammonium hydroxide and that ammonium hydroxide is formed by dissolution of ammonia in water. It has now been discovered that these three chemicals form a nanocrystal etchant that is highly selective to oxide. Sufficiently highly selective so that even at 60 Angstroms for protective layer 20 and 120 Angstroms for the nanocrystals, there is sufficient margin to ensure that protective layer 20, even after the removal of the exposed nanocrystals, can still be used for protecting substrate 12 from a subsequent source/drain implant. There is some etching also of the remaining portions of control gate layer 30, but the etch rate is significantly greater on the nanocrystals so the reduction of control gate layer 30 during the etch does not cause a problem.

Typical usage of SC1 is at room temperature, but the speed of etching of the nanocrystals has been found to be increased significantly by elevating the temperature, especially above 50 degrees Celsius. This elevating of the temperature has not been found to degrade the selectivity of etching between polysilicon and oxide. Similarly, increasing the concentration of the ammonium hydroxide has been found to improve the speed of etching of the polysilicon while not adversely impacting the selectivity of etching between polysilicon and oxide. Keeping the concentration of hydrogen peroxide solution the same as the ammonium hydroxide solution has been found to be effective as well. These need not necessarily be kept the same however. Although other combinations may be found to be just as effective or even more effective, one combination that has been found to be particularly effective is 9:1:1 by volume at a temperature of 60 degrees Celsius; that is to say 9 parts pure water, 1 part ammonium hydroxide solution (solution from 29.4% ammonia), and 1 part hydrogen peroxide solution (30% by weight of hydrogen peroxide). This same solution can be achieved by using less of a solution hydrogen peroxide but in which the percentage of hydrogen peroxide is higher. Similarly, the same solution can be achieved by using a lesser amount of solution of ammonium hydroxide having a higher concentration of ammonia than the 29.4% that is currently readily available commercially. Regardless of the actual concentrations available for use or those actually used, it is desirable that the resulting ratio of pure water to ammonium hydroxide be equivalent to or less than 10 to 1 by volume in which the ammonium hydroxide is from a solution of 29.4% ammonia by weight. This is similarly the case for the hydrogen peroxide, regardless of the actual concentrations available for use or those actually used, it is desirable that the resulting ratio of pure water to hydrogen peroxide be equivalent to or less than 10 to 1 by volume in which the hydrogen peroxide is from a solution of 30% hydrogen peroxide by weight.

Shown in FIG. 6 is semiconductor device 10 as a pair of NVM cells 32 and 34 that are designed for source side injection programming. Shown is source 36 of NVM cell 32, drain 38 that is common for both NVM cells 32 and 34, and a source 40 for NVM cell 34. The implants for source/drains 36, 38, and 40 may be advantageously performed through protective layer 20. An alternative would be to remove protective layer 20 and forming another layer protecting substrate 12 during the implant.

By now it should be appreciated that there has been provided a method for forming a semiconductor structure. The method includes providing a semiconductor layer. The method further includes forming nanocrystals over the semiconductor layer. The method further includes using a solution comprising pure water, hydrogen peroxide, and ammonium hydroxide to remove at least a portion of the nanocrystals. The method may be further characterized by a ratio by volume of pure water to ammonium hydroxide of the solution being equivalent to or less than a ratio by volume of 10:1 of pure water to ammonium hydroxide when ammonium hydroxide has a concentration of 29% ammonia by weight. The method may be further characterized by the step of using the solution to remove the at least a portion of the nanocrystals being performed at a temperature of 50 degrees Celsius or more. The method may further comprise forming an oxide layer over the semiconductor layer, wherein the forming the nanocrystals over the semiconductor layer comprises forming the nanocrystals directly on the oxide layer. The method may be further characterized by the nanocrystals comprising silicon. The method may be further characterized by an average diameter of the nanocrystals being greater than an average thickness of the oxide layer. The method may be further characterized by a ratio by volume of water to ammonium hydroxide to hydrogen peroxide of the solution being x:1:1 where x is 10 or less, wherein the ammonium hydroxide of the solution has a concentration of 29% ammonia by weight and the hydrogen peroxide of the solution has a concentration of 30% by weight.

Also provided is a method for forming a semiconductor structure. The method includes providing a semiconductor layer. The method further includes forming a gate dielectric over the semiconductor layer. The method further includes forming a select gate over the gate dielectric. The method further includes forming nanocrystals over the select gate and the semiconductor layer. The method further includes forming a control gate over the nanocrystals. The method further includes using a solution comprising water, hydrogen peroxide, and ammonium hydroxide to remove exposed portions of the nanocrystals. The method may be further characterized by a ratio by volume of pure water to ammonium hydroxide of the solution being equivalent to or less than a ratio by volume of 10:1 of pure water to ammonium hydroxide when ammonium hydroxide has a concentration of 29% ammonia by weight. The method may be further characterized by the step of using the solution to remove the exposed portions of the nanocrystals being performed at a temperature of 50 degrees Celsius or more. The method may be further characterized by the step of using the solution to remove the exposed portions of the nanocrystals being performed at a temperature of 50 degrees Celsius or more. The method may be further characterized by the nanocrystals comprising silicon. The method may further comprise forming a tunnel oxide over the semiconductor layer and along a sidewall of the select gate, wherein forming the nanocrystals over the select gate and the semiconductor layer comprises forming the nanocrystals over the tunnel oxide.

Disclosed also is a method for forming a semiconductor structure. The method includes providing a semiconductor layer. The method further includes forming silicon nanocrystals over the semiconductor layer. The method further includes using a solution comprising water, hydrogen peroxide, and ammonium hydroxide to remove at least a portion of the silicon nanocrystals, wherein a temperature of the solution is 50 degrees Celsius or more and a ratio by volume of pure water to ammonium hydroxide of the solution is equivalent to or less than a ratio by volume of 10:1 of pure water to ammonium hydroxide when ammonium hydroxide has a concentration of 29% ammonia by weight or less. The method may be further characterized by the temperature of the solution being 60 degrees Celsius or more. The method may be further characterized by a ratio by volume of water to ammonium hydroxide to hydrogen peroxide of the solution being x:1:1 where x is 10 or less, wherein the ammonium hydroxide of the solution has a concentration of 29% ammonia by weight and the hydrogen peroxide of the solution has a concentration of 30% by weight. The method may further comprise forming an oxide layer over the semiconductor layer, wherein the forming the silicon nanocrystals over the semiconductor layer comprises forming the silicon nanocrystals directly on the oxide layer. The method may be further characterized by an average diameter of the silicon nanocrystals being greater than an average thickness of the oxide layer. The method may be further characterized by forming a gate dielectric over the semiconductor layer, forming a select gate over the gate dielectric layer, forming a tunnel oxide over the semiconductor layer and a sidewall of the select gate, wherein the forming the silicon nanocrystals over the semiconductor layer comprises forming the silicon nanocrystals over the tunnel oxide, and forming a control gate over the nanocrystals, wherein the using the solution comprising water, hydrogen peroxide, and ammonium hydroxide to remove at least a portion of the silicon nanocrystals is performed after the forming the control gate to remove exposed portions of the silicon nanocrystals.

Although the invention is described herein with reference to specific embodiments, various modifications and changes can be made without departing from the scope of the present invention as set forth in the claims below. For example, there was no specific mention of deuterium, but deuterium could be used in place of regular hydrogen in forming the various materials described. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

1. A method for forming a semiconductor structure, the method comprising:
providing a semiconductor layer;
forming nanocrystals over the semiconductor layer; and
using a solution comprising pure water, hydrogen peroxide, and ammonium hydroxide to remove at least a portion of the nanocrystals performed at a temperature of more than 50 degrees Celsius, wherein equal parts of ammonium hydroxide and hydrogen peroxide are used.

2. The method of claim 1, wherein a ratio by volume of pure water to ammonium hydroxide of the solution is equivalent to or less than a ratio by volume of 10:1 of pure water to ammonium hydroxide when ammonium hydroxide has a concentration of 29% ammonia by weight.

3-4. (canceled)

5. The method of claim 1, wherein the nanocrystals comprise silicon.

6. The method of claim 1, further comprising:
forming an oxide layer over the semiconductor layer, wherein the forming the nanocrystals over the semiconductor layer comprises forming the nanocrystals directly on the oxide layer.

7. The method of claim 6, wherein an average diameter of the nanocrystals is greater than an average thickness of the oxide layer.

8. The method of claim 1, wherein a ratio by volume of water to ammonium hydroxide to hydrogen peroxide of the solution is x:1:1 where x is 10 or less, wherein the ammonium hydroxide of the solution has a concentration of 29% ammonia by weight and the hydrogen peroxide of the solution has a concentration of 30% by weight.

9. A method for forming a semiconductor structure comprising:
providing a semiconductor layer;
forming a gate dielectric over the semiconductor layer;
forming a select gate over the gate dielectric;
forming nanocrystals over the select gate and the semiconductor layer;
forming a control gate over the nanocrystals; and
using a solution at a temperature above 50 degrees Celsius comprising water, hydrogen peroxide, and ammonium hydroxide to remove exposed portions of the nanocrystals, wherein the solution comprises equal parts of hydrogen peroxide and ammonium hydroxide.

10. The method of claim 9, wherein a ratio by volume of pure water to ammonium hydroxide of the solution is equivalent to or less than a ratio by volume of 10:1 of pure water to ammonium hydroxide when ammonium hydroxide has a concentration of 29% ammonia by weight.

11-12. (canceled)

14. The method of claim 9, further comprising:
forming a tunnel oxide over the semiconductor layer and along a sidewall of the select gate, wherein forming the nanocrystals over the select gate and the semiconductor layer comprises forming the nanocrystals over the tunnel oxide.

15. A method for forming a semiconductor structure, the method comprising:
providing a semiconductor layer;
forming silicon nanocrystals over the semiconductor layer; and
using a solution comprising water, hydrogen peroxide, and ammonium hydroxide to remove at least a portion of the silicon nanocrystals, wherein a temperature of the solution is more than 50 degrees Celsius and a ratio by volume of pure water to ammonium hydroxide of the solution is equivalent to or less than a ratio by volume of 10:1 of pure water to ammonium hydroxide when ammonium hydroxide has a concentration of 29% ammonia by weight or less and the solution has equal parts hydrogen peroxide and ammonium hydroxide.

16. The method of claim 15, wherein the temperature of the solution is 60 degrees Celsius or more.

17. The method of claim 15, wherein a ratio by volume of water to ammonium hydroxide to hydrogen peroxide of the solution is x:1:1 where x is 10 or less, wherein the ammonium hydroxide of the solution has a concentration of 29% ammonia by weight and the hydrogen peroxide of the solution has a concentration of 30% by weight.

18. The method of claim 15, further comprising:
forming an oxide layer over the semiconductor layer, wherein the forming the silicon nanocrystals over the semiconductor layer comprises forming the silicon nanocrystals directly on the oxide layer.

19. The method of claim 18, wherein an average diameter of the silicon nanocrystals is greater than an average thickness of the oxide layer.

20. The method of claim 15, further comprising:
forming a gate dielectric over the semiconductor layer;
forming a select gate over the gate dielectric layer;
forming a tunnel oxide over the semiconductor layer and a sidewall of the select gate, wherein the forming the silicon nanocrystals over the semiconductor layer comprises forming the silicon nanocrystals over the tunnel oxide; and
forming a control gate over the nanocrystals, wherein the using the solution comprising water, hydrogen peroxide, and ammonium hydroxide to remove at least a portion of the silicon nanocrystals is performed after the forming the control gate to remove exposed portions of the silicon nanocrystals.
